(19) United States
(12) Patent Application Publication
(10) Pub. No.: US 2012/0012380 A1
(43) Pub. Date: Jan. 19, 2012

(54) Back Drill Verification Feature

(76) Inventor: Joseph P. Miller, Cypress, TX (US)

(21) Appl. No.: 13/259,081

(22) PCT Filed: Apr. 13, 2009
(86) PCT No.: PCT/US09/40337

§ 371 Date: Sep. 22, 2011

(51) Int. Cl. H05K 1/11; H01K 3/10

(52) U.S. Cl. 174/264; 29/852

(57) ABSTRACT

A back drill verification feature is provided on a layer of a circuit board. Before a back drill operation is performed, an electrical connection exists between conductive material in a via hole and the back drill verification feature. After the back drill operation, the electrical connection is severed.

### BACKGROUND

Circuit boards are often formed having multiple layers, with signal traces provided on inner and outer layers of the circuit board. To connect a signal trace on an inner layer of the board to a component, connector, or signal trace on an outer layer of the board, or to connect two signal traces on different inner layers, a via hole is drilled through the board that intersects one or more signal traces. Thereafter, the interior of the via hole is plated with a conductive material, thereby creating a conductive path from the signal trace on the inner layer to a component, connector, or signal trace on the outer layer, or to a signal trace on different layer.

Often an unneeded portion, or stub, of conductive material will remain. For example, if a signal trace is approximately midway between an upper and lower layer of the board, and a component or connector is coupled to the upper layer, an unneeded stub remains between the signal trace and the lower layer of the board. When high frequency signals are carried between the signal trace and the component, connector, or other signal trace, the unneeded stub can create an undesirable reflection, thereby reducing the maximum frequency that can be carried by the signal trace through the via hole to the component, connector, or other signal trace.

To increase the performance of circuit boards, boards are back drilled to remove unneeded stubs. A back drilling operation removes the conductive material from the via hole by drilling into the via hole with a drill hit slightly larger than the via hole. The drilling operation is performed from the layer of the board having the unneeded stub. For example, in the example mentioned above having a component or connector on the upper layer of the board, the back drill operation is performed from the lower layer of the board. The drill bit drills as close as practical to the signal trace, without breaking the connection between the signal trace and the conductive material in the via hole that completes the connection to the component, connector, or other signal trace.

### BRIEF DESCRIPTION OF THE DRAWINGS

The Figures depict embodiments, implementations, and configurations of the invention, and not the invention itself.

FIG. 1 is a perspective view of a typical electronic device, such as a computer system, in which embodiments of the present invention may be deployed.

FIGS. 2-4 are side cutaway views of a circuit board, and illustrate a typical back drill operation.

FIGS. 5-13 and 15 are side cutaway views of a circuit board shown in FIG. 1, and illustrate back drill verification features in accordance with embodiments of the present invention.

FIG. 14 is a sectional view taken along section line 14-14 of FIG. 13.

FIG. 16 is a sectional view taken along section line 16-16 of FIG. 15.

FIG. 17 shows a test signal.

### DETAILED DESCRIPTION

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will, appreciate numerous modifications and variations therefrom. It is intended that the appended claims cover such modifications and variations as fall within the true spirit and scope of the invention.

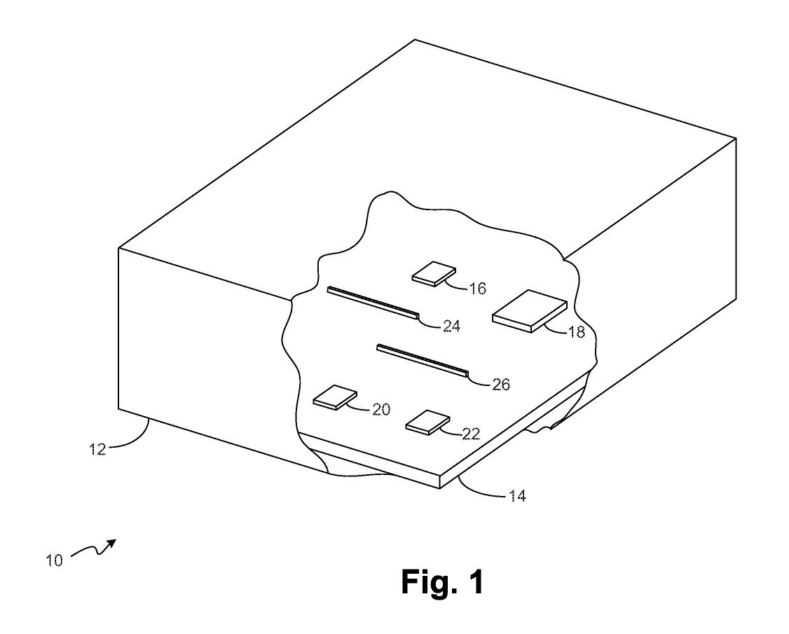

Embodiments of the present invention relate to a back drill verification feature that increases the detectability of a missed or improper back drill operation. FIG. 1 is a perspective view of a typical electronic device 10, such as a computer system, in which embodiments of the present invention may be deployed. Device 10 has an enclosure 12 and a circuit board 14. Attached to circuit board 14 are components and connectors, such as components 16, 18, 20, and 22, and connectors 24 and 26. Note that FIG. 1 is merely representative, and the present invention may be deployed in any product having a multi-layer circuit board, such as an add-on card configured to be installed in a computer system.

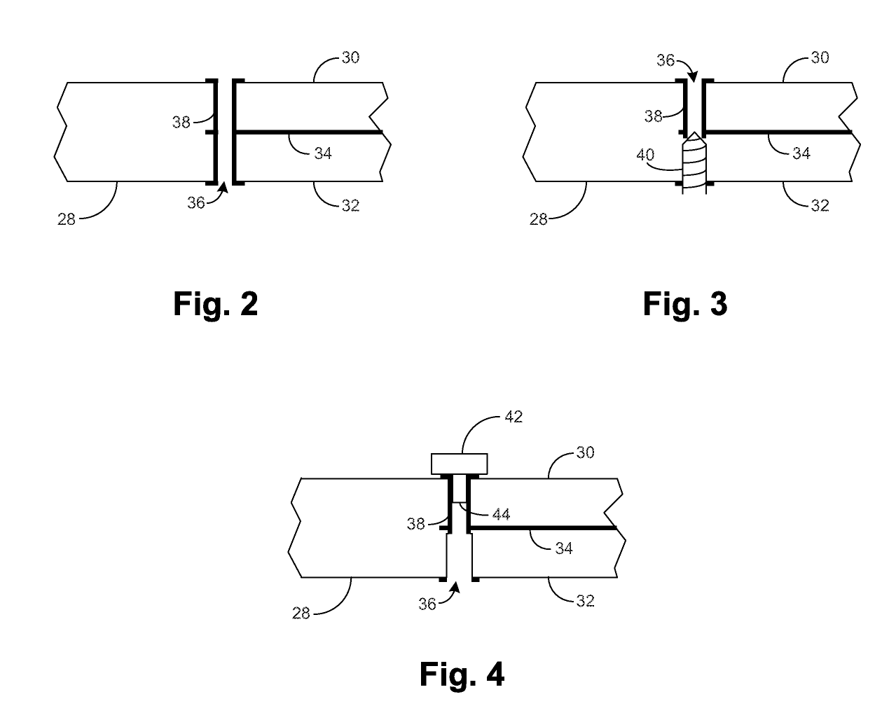

FIGS. 2-4 are side cutaway views that illustrate a typical back drill operation. FIGS. 2-4 illustrate a via that connects a signal trace on an inner layer of the board to a connector or component on an outer layer of the board. However, those skilled in the art will recognize that back drill operations may also be performed on vias that connect signal traces on two or more different board layers.

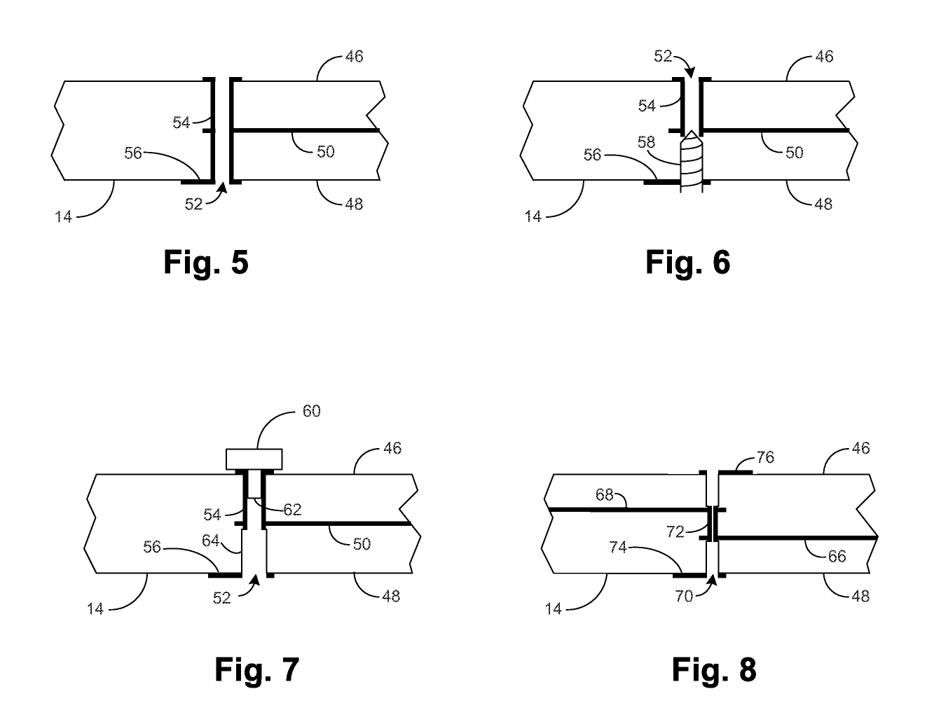

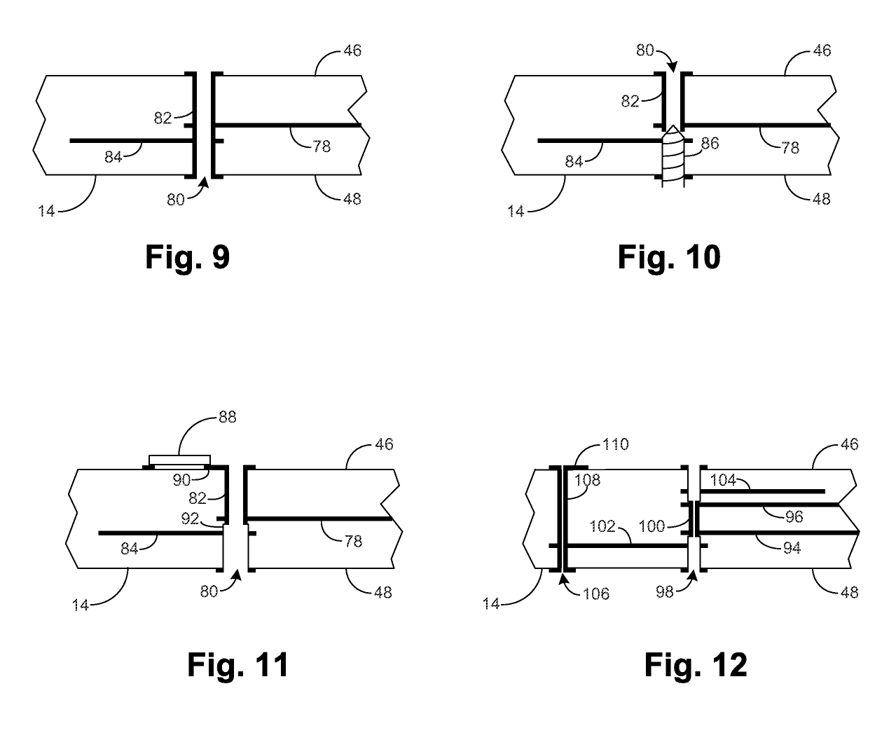

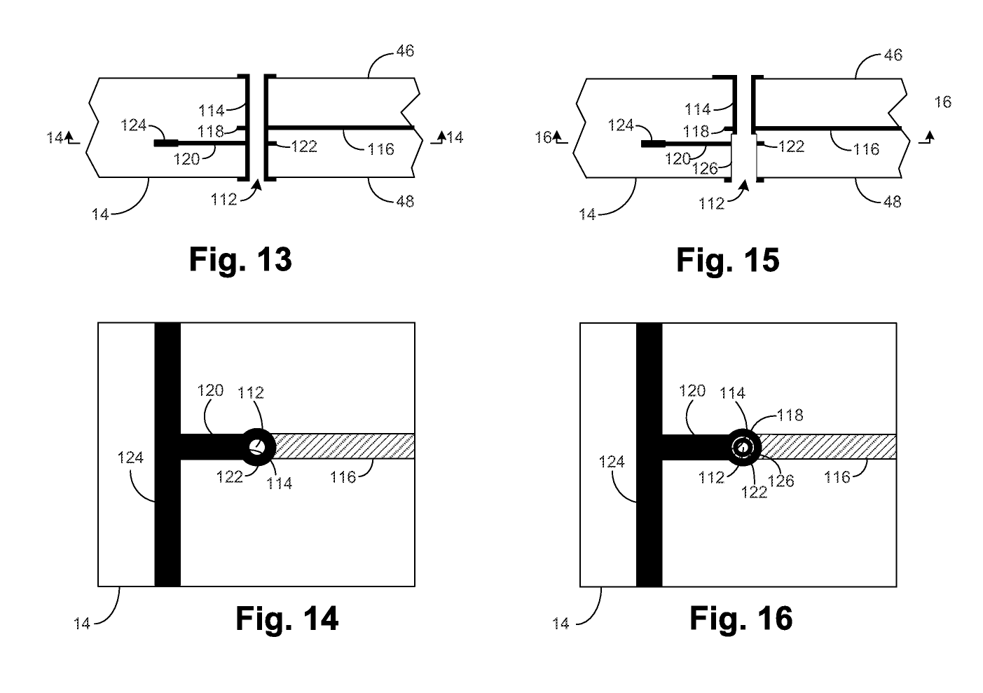

In FIG. 2, board 28 has upper layer 30, lower layer 32, and an inner layer having a signal trace 34. Upper layer 30 and lower layer 32 are both outer layers. A via hole 36 was drilled through board 28, and the interior of via hole 36 was plated with conductive material 38. Note that a layer having a signal trace in electrical contact with conductive material 38 includes an annular ring that surrounds the via hole. In FIG. 2-4 (as well as FIGS. 5-13 and 15), the annular ring is represented by the small stub on the side of the via hole opposite the side having the signal trace. The annular ring is shown in greater detail in the embodiment of the present invention shown in FIGS. 14 and 16.

As will be seen in FIG. 4, a connector will be mounted on upper layer 30 of board 28. In FIG. 2, note the stub of conductive material 38 that remains between signal trace 34 and lower layer 32 aboard 28.

In FIG. 3, a back drill operation is performed by drill bit 40 drilling into via hole 36 from lower layer 32 and removing the unneeded stub of conductive material 38. Drill bit 40 has a diameter slightly larger than the diameter of via hole 36.

FIG. 4 shows the result of the back drill operation. Also shown in FIG. 4 is connector 42, which has a pin 44 in electrical contact with conductive material 38, thereby completing the connection between signal trace 34 and pin 44 of connector 42. Note that connector 42 is merely representative, and conductive material 38 may be coupled to surface mounted components or connectors by other traces and pads, as will be shown in embodiments of the invention described below. The unneeded stub of conductive material 38 has been removed from via hole 36, thereby reducing signal reflections along the signal path from signal trace 34 to pin 44 of connector 42.

Although it may happen rarely, a back drill operation can be missed, or the back drill operation may not be performed properly. While back drilling provides a benefit, the effect can be small.

The velocity of propagation in a circuit board is given by:

$${V}_{p} = \frac{C}{\sqrt{{ɛ}_{r}}}$$

where:

C=approximately 3*10⁸ meters per second, or about 30 cm/ns

∈ᵣ=effective dielectric constant

Vₚ=velocity of propagation

Typical circuit board materials have an effective dielectric constant of 3.7-4.2, while more exotic and specialized circuit board materials may have an effective dielectric constant of 2.0-6.0.

Assume that a circuit board has an effective dielectric constant of 4, and a signal path on the board carries a 5 GHz signal. The wavelength of the signal is approximately 30 millimeters. If the board is 5 millimeters thick, and the signal trace is in the middle of the board, the back drilling operation will remove a stub having a length of approximately 2.5 millimeters.

A 2.5 millimeter stub will produce a small reflection, and therefore it is beneficial to remove the stub. However, a reflection will not cause a major degradation in signal quality until the conductor causing the reflection has a length of at least one-eighth of a wavelength or greater. In general, there is a continuum from very small fractions of wavelengths that cause minor degradations to a severe degradation at one-fourth of a wavelength. For a 5 GHz signal carried by the signal path mentioned above, one-eighth of a wavelength is 3.75 millimeters. Therefore, the relatively small reflection caused by the unneeded stub creates a correspondingly small degradation in the signal.

Testing for a missed or improper back drill operation can be difficult, since the small degradation in the signal could also be caused by other factors, such as a poor connection between a pin and the conductive material in a via hole, or a poorly formed signal trace.

Embodiments of the present invention expose a missed or improperly performed back drill operation. A back drill verification feature is provided that intersects a via hole at a different layer than a signal trace. Before the back drill operation is performed, a conductive path is present between the back drill verification feature and the conductive material in the via hole. The back drill operation severs the connection between the conductive material and the via hole.

In one embodiment, the back drill verification feature has a length tuned to create a detectable reflection at a testing frequency. In another embodiment, the back drill verification feature is configured to be accessible to a circuit board tester, such as a “bed of nails” tester. If the portion of the back drill verification feature that intersects the via hole comprises a signal trace that is provided on an outer layer of the circuit board, the back drill verification feature may be accessed directly from the outer layer by making contact with the signal trace of the back drill verification feature. Alternatively, if the portion of the back drill verification feature that intersects the via hole comprises a signal trace that is provided on an inner layer of the circuit board, the back drill verification feature may include a via hole with conductive material provided therein to cause the back drill verification feature to be accessible at an outer layer of the circuit board. In yet another embodiment, the back drill verification feature is configured to create a short between a signal trace and another signal, such as a power or ground signal.

Circuit boards upon which back drill operations are performed have typical thicknesses of two millimeters to six millimeters. Furthermore, modem circuit boards may have 30 or more layers. Via holes drilled to connect a signal trace from an inner layer to a component or connector on an outer layer of the circuit board are typically 0.5-1.0 millimeters in diameter. However, via holes may also be used to connect two signal traces present on different layers, as will be discussed in greater detail below. Typically, a via hole for connecting signal traces on different layers is approximately 0.3 millimeters in diameter.

Note that in the Figures discussed herein, the relative scales of various features have been selected to illustrate more clearly embodiments of the present invention. However, when embodiments of the present invention are deployed in an actual circuit board, dimensions, such as the exemplary dimensions discussed above, will be used. Also note that multilayer boards are formed having signal traces on multiple layers, with electrical insulation provided between the layers, as is known in the art. To more clearly illustrate the present invention, only the signal traces are shown.

FIGS. 5-8 are side cutaway views that illustrate embodiments of the present invention having back drill verification features that initially intersect conductive material in via holes at outer layers of a circuit board. Embodiments of the present invention may deployed in circuit board 14 of electronic device 10 shown in FIG. 1, as well as other devices employing circuit boards, as are known in the art.

In FIG. 5, circuit board 14 has upper layer 46, lower layer 48, and an inner layer having signal trace 50. Upper layer 46 and lower layer 48 are outer layers. Via hole 52 was drilled through board 14, and via hole 52 was plated with conductive material 54. As will be discussed below with reference to FIG. 7, a connector 60 will be mounted to upper layer 46 of board 14. A stub of conductive material 54 that remains between signal trace 50 and lower layer 48 of circuit board 14 is electrically coupled to back drill verification feature 56.

In FIG. 6, a back drill operation is performed by drill bit 58 drilling into via hole 52 from lower layer 48 and removing the unneeded stub of conductive material 54. The back drill operation also severs the electrical connection between conductive material 54 and back drill verification feature 56.

The results are shown in FIG. 7. Note that FIG. 7 includes connector 60, which has a pin 62 in electrical contact with conductive material 54, thereby completing the electrical connection between signal trace 50 and pin 62 of connector 60. Connector 60 may represent any of the connectors 24 or 26 shown in FIG. 1. Also note that the conductive material in a via hole may couple a signal trace to a surface mounted component or connector, as shown in the embodiment of FIG. 11, which will be discussed below.

Note the gap 64 created by the back drill operation between conductive material 54 and back drill verification feature 56. Gap 64 electrically isolates back drill verification feature 56 from conductive material 54.

FIGS. 5-7 illustrate embodiments suitable for a via hole that couples a signal trace on an inner layer to a component or connector on an outer layer of a circuit board. A similar technique may be used to couple a first signal trace on an inner layer to a second signal trace on an outer layer of a circuit board. As mentioned above, a via hole can also be used to connect two signal traces present on different inner layers of a circuit board. Such a configuration is shown in FIG. 8, in accordance with an embodiment of the present invention.

In FIG. 8, board 14 has signal trace 66 provided on a first inner layer and signal trace 68 provided on a second inner layer. Two back drill operations, similar to the back drill operation shown in FIG. 6, have been performed, with a first back drill operation into via hole 70 from lower layer 48 of board 14 approaching signal trace 66, and a second back drill operation into via hole 70 from upper layer 46 of board 14 approaching signal trace 68. The unneeded stubs of conductive material 72 from signal trace 68 to upper layer 46 of board 14, and from signal trace 66 to lower layer 48 of board 14 have been removed. Conductive material 72 remaining after the first and second back drill operations electrically couples signal traces 66 and 68.

Back drill verification feature 74 on lower layer 48 of board 14 was electrically coupled to conductive material 72 before the first back drill operation, and the first back drill operation severed the connection between back drill verification feature 74 and conductive material 72. Similarly, back drill verification feature 76 on upper layer 46 of board 14 was electrically coupled to conductive material 72 before the second back drill operation, and the second back drill operation severed the connection between back drill verification feature 76 and conductive material 72.

FIGS. 9-12 are side cutaway views that illustrate embodiments of the present invention having back drill verification features that initially intersect conductive material in via holes at inner layers of a circuit board. Embodiments of the present invention may deployed in circuit board 14 of electronic device 10 shown in FIG. 1, as well as other devices employing circuit boards, as are known in the art.

In FIG. 9, circuit board 14 has upper layer 46, lower layer 48, and an inner layer having signal trace 78. Upper layer 46 and lower layer 48 are outer layers. A via hole 80 was drilled through board 14, and the via hole was plated with conductive material 82. As will be discussed below with reference to FIG. 11, a surface mounted component 88 will be mounted to upper layer 46 of board 14. A stub of conductive material 82 that remains between signal trace 78 and lower layer 48 of circuit board 14 is electrically coupled to back drill verification feature 84

In FIG. 10, a back drill operation is performed by drill bit 86 drilling into via hole 80 from lower layer 48 and removing the unneeded stub of conductive material 82. The back drill operation also severs the electrical connection between conductive material 82 and back drill verification feature 84.

In the embodiments shown in FIGS. 5-8, an advantage provided by having the back drill testability feature on an outer layer of the circuit board is that a spring pin of a circuit tester can easily probe the back drill testability feature. However, the back drill operation severs the connection between the back drill testability feature and the conductive material in the via hole as soon as the drill bit penetrates the outer layer of the board. Accordingly, the embodiments shown in FIGS. 5-8 do not verify that the back drill operation was performed to a proper depth.

In contrast, the embodiments shown in FIGS. 9-12 can verify that the back drill operation was performed to a proper depth. Ideally, back drill testability feature 84 is provided on a layer as close as possible to signal trace 78, while maintaining sufficient separation to ensure that a proper back drill operation will sever the connection between back drill testability feature 84 and conductive material 82, without severing the connection between signal trace 78 and conductive material 82. Of course, back drill testability feature 84 may be provided on a layer more distant from signal trace 78, with the ability to detect proper drill depth diminishing in proportion with the number of layers separating signal trace 78 and back drill testability feature 84.

The results of the back drill operation shown in FIG. 10 are shown in FIG. 11. Note that FIG. 11 includes surface mounted component 88, which is coupled to conductive material 82 via pad 90, thereby completing the electrical connection between signal trace 78 and component 88. Component 88 may represent any of the components 16, 18, 20, or 22 shown in FIG. 1. As mentioned above, the conductive material in a via hole may also couple a signal trace to a surface mounted connector. As shown in FIG. 7, the conductive material in a via hole may couple a signal trace to a connector having a pin. Any of these methods may be used with the various embodiments of the present invention to couple components and connectors to signal traces on inner layers, along with other appropriate methods known in the art.

Note the gap 92 between conductive material 82 and back drill verification feature 84, which was created by the back drill operation. Gap 92 electrically isolates back drill verification feature 84 from conductive material 82.

FIGS. 9-11 illustrate embodiments suitable for a via hole that couples a signal trace on an inner layer to a component or connector on an outer layer of a circuit board. A similar technique may be used to couple a first signal trace on an inner layer to a second signal trace on an outer layer of a circuit board. As mentioned above, a via hole can also be used to connect two signal traces present on different inner layers of a circuit board. Such a configuration is shown in FIG. 12, in accordance with embodiments of the present invention. FIG. 12 also includes a back drill testability feature that has a via hole with conductive material provided therein to allow the back drill testability feature to be probed at an outer layer of the circuit board, in accordance with embodiments of the invention.

In FIG. 12, board 14 has signal trace 94 provided on a first inner layer, and signal trace 96 provided on a second inner layer. Two back drill operations, similar to the back drill operation shown in FIG. 10, have been performed, with a first back drill operation into via hole 98 from lower layer 48 of board 14 approaching signal trace 94, and a second back drill operation into via hole 98 from upper layer 46 of board 14 approaching signal trace 96. The unneeded stubs of conductive material 100 from signal trace 96 to upper layer 46 of board 14, and from signal trace 94 to lower layer 48 of board 14 have been removed. Conductive material 100 remaining after the first and second back drill operations electrically couples signal traces 94 and 96.

Back drill verification feature 102 was electrically coupled to conductive material 100 before the first back drill operation, and the first back drill operation severed the connection between back drill verification feature 102 and conductive material 100. Similarly, back drill verification feature 104 was electrically coupled to conductive material 100 before the second back drill operation, and the second back drill operation severed the connection between back drill verification feature 104 and conductive material 100.

When using a circuit board tester with the embodiment shown in FIGS. 5-8, a spring pin of a circuit board tester can make contact with back drill verification feature 56 of FIGS. 5-7, and back drill verification features 74 and 76 of FIG. 8, all of which are provided on an outer layer of board 14. Such testers are sometimes known in the art as “bed of nails” testers. With back drill verification features 84 and 104 shown in FIGS. 9-12, a circuit board tester cannot make direct contact with back drill verification features 84 and 104 (provided there are proper back drill operations) since features 84 and 104 are provided on inner layers and are not routed to an outer layer of board 14.

However, back drill verification feature 102 in FIG. 12 includes a via hole 106 having an interior plated with conductive material 108, in accordance with an embodiment of the present invention. Accordingly, back drill verification feature 102 may be probed at pad 110 by a spring pin of a circuit board tester.

If the circuit tester finds electrical continuity between the back drill verification feature and the signal trace to which the back drill verification feature would have been electrically coupled before a proper back drill operation, then the back drill operation was missed, or was not properly performed. When using an embodiment of the present invention designed for use with a circuit board tester, the portion of the back drill verification feature present on an outer layer need only be large enough to serve as a test pad (e.g., 0.1-2.0 millimeters).

As discussed above, in various embodiments, a missed or improper back drill operation may also be detected by a back drill verification feature having a length tuned to a test frequency. In these embodiments, the back drill verification feature creates a detectable reflection at the test frequency.

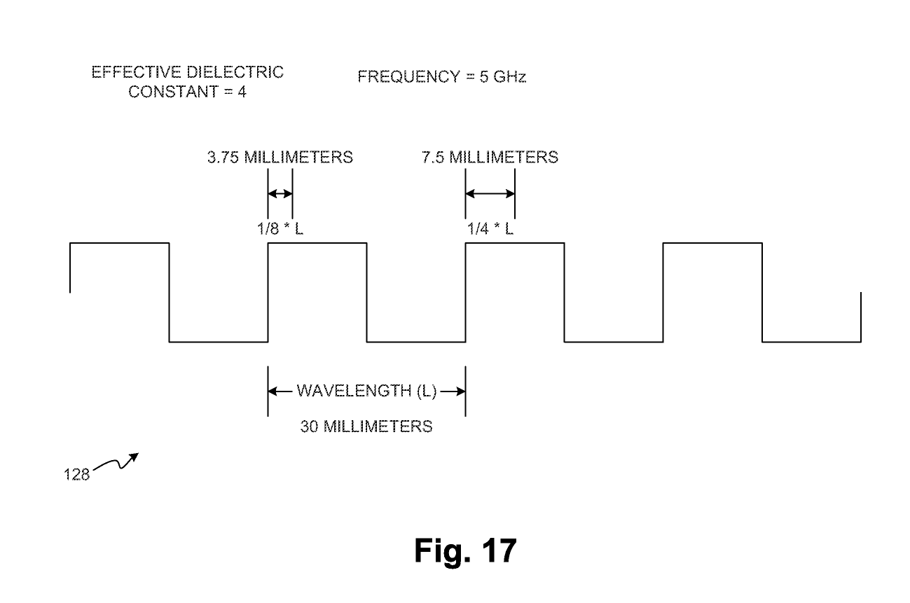

Consider the example of a signal trace carrying a test signal having a frequency of 5 GHz on a circuit board having an effective dielectric constant of 4, such as test signal 128 of FIG. 17. Test signal 128 has a wavelength of approximately 30 millimeters. Note that test signal 128, which is shown as a square wave, is merely representative, and embodiments of the present invention may be used with many other types of test signals, such as signals carrying data strings having minimum bit lengths of one-half of a wavelength.

Typically, a reflection will begin to cause a substantial degradation in signal quality, and therefore begin to become easy to detect, when the length of the conductor causing the reflection is at least one-eighth the wavelength of the test signal, which in this example is 3.75 millimeters. A very detectable reflection will be created when the length of the conductor causing the reflection is at least one-fourth the wavelength of the test signal, which in this case is 7.5 millimeters. As mentioned above, there is a continuum from very small fractions of wavelengths that cause minor degradations to a severe degradation at one-fourth of a wavelength. By providing a back drill verification feature having a length tuned to a test frequency, the back drill verification feature creates a reflection that is easy to detect.

The reflection may be detected when a bare board is tested on a circuit board tester by applying the test signal at one end of a signal path before a via hole having a back drill operation to be verified, and measuring test signal at another end of the signal path after the via hole. Alternatively, the reflection may be detected in a completed circuit board. For example, many signal paths are verified by parity bits or cyclical redundancy code (CRC) bits. By providing a back drill verification feature tuned approximately to the test frequency carried by the signal trace, an improper or missing back drill operation is easily detected by running in-circuit test routines and diagnostics that transmit signals at frequencies having wavelengths roughly matched to the lengths of the back drill verification features, as described above. The in-circuit test routines and diagnostics may be invoked by a circuit tester exercising the completed board and invoking various testing features, such as boundary scans, and by applying signals to I/O pins. Also the in-circuit test routines and diagnostics may be invoked in the completed device. In these embodiments, all of the back drill verification features shown in FIGS. 5-12 may be provided with lengths appropriate for detecting reflections.

Finally, in another embodiment, the presence or absence of a short between the back drill verification feature and another signal, such as a power or ground signal may be used to detect a missing or improper back drill operation. This embodiment is shown in FIGS. 13-16.

FIG. 13 shows this embodiment before a back drill operation. In FIG. 13, board 14 has upper layer 46 and lower layer 48. Via hole 112 was drilled through board 14 and plated with conductive material 114. Signal trace 116 is provided on an inner layer of board 14 and is in electrical contact with conductive material 114 via annular ring 118. Back drill testability feature 120 is in electrical contact with conductive material 114 via annular ring 122, and is also in electrical contact with signal trace 124, which is transverse to back drill testability feature 120 and can be visualized as running perpendicular to the two-dimensional plane represented by FIG. 13. Note that signal trace 124 is shown as being slightly larger than back drill testability feature 120 merely to highlight signal trace 124.

FIG. 14 is a sectional view of circuit board 14 taken along section line 14-14 of FIG. 13. Like FIG. 13, FIG. 14 also shows board 14 before a back drill operation. Accordingly, signal trace 124 is coupled to back drill testability feature 120, which in turn is coupled to conductive material 114 via annular ring 122. Signal trace 116 (shown in phantom) is also coupled to conductive material 114.

FIG. 15 shows circuit board 14 after a back drill operation, such as the back drill operations shown in FIGS. 6 and 10. Accordingly, the back drill operation created gap 126 and severed the connection between signal trace 116 and back drill testability feature 120.

FIG. 16 is a sectional view of circuit board 14 taken along section line 16-16 of FIG. 15. Like FIG. 15, FIG. 16 also shows board 14 after the back drill operation. As seen in FIG. 14, conductive material 114 remains in electrical contact with annular ring 118 and signal trace 116 (both shown in phantom). However, gap 126 separates conductive material 114 from annular ring 122 and back drill testability feature 120.

Note that in other embodiments, back drill verification feature 120 and signal trace 124 may be provided on outer layers. Furthermore, back drill verification feature 120 and signal trace 124 may be provided on different layers and connected by a via hole (which is not shown in FIGS. 13-16).

In this embodiment, an improper or missing back drill operation is detected by an electrical connection between conductive material 114 in via hole 112 (which will be coupled to other signal traces, connectors, or components), and signal trace 124. Note that after the back drill operation, back drill verification feature 120 remains electrically coupled to signal trace 124, thereby adding a small amount of additional capacitance to signal trace 124, and possibly creating a reflection for high frequency signals. Accordingly, it is desirable that signal trace 124 carry a low frequency or DC signal, such a ground signal or a supply voltage. Of course, any signal trace carrying any signal which is not significantly affected by the presence of the additional trace material that forms back drill verification feature 120 may be used. For example, signal trace 124 could carry a signal that is coupled to a status indicator LED on circuit board 14.

When a circuit board having this embodiment of the present invention is placed in a “bed of nails” test fixture, and a proper back drill operation has not been performed, the tester will detect an improper electrical connection from signal trace 124 through back drill verification feature 120 to the conductive material 114 in via hole 112. If connectivity is not present, the back drill operation has been performed properly. Of course, if a circuit board 14 with this embodiment is fully assembled, and back drill operations were not properly performed, the board may not function. Whether the circuit board functions will be dependent on which back drill operations were not performed properly, and the signal carried by signal trace 124. In any event, the improper or missing back drill operation will be detected by the fact that the board does not function, or does not function properly, or the improper or missing back drill operation will be detected by test routines and diagnostic routines performed by components on circuit board 14.

Embodiments of the present invention exaggerate effects associated with a failure to perform a back drill operation, or an improperly performed back drill operation. The present invention causes missing or improper back drill operations to be easily detected by a board tester, or in-circuit test routines and diagnostics. Embodiments of the present invention may be implemented with little additional cost, since all that is needed are the signal traces that form the back drill verification features, in accordance with embodiments of the present invention.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A circuit board (14) comprising:
a first signal trace (50, 66, 78, 94, 116) present on a first inner layer of the circuit board (14);
a via hole (52, 70, 80, 98, 112) drilled through the circuit board (14) and intersecting the first signal trace (50, 66, 78, 94, 116);
conductive material (54, 72, 82, 100, 114) in the via hole (52, 70, 80, 98, 112) and in electrical contact with the first signal trace (50, 66, 78, 94, 116); and
a first back drill verification feature (56, 74, 84, 102, 120) on a first layer of the circuit board (14), wherein the first inner layer and the first layer are different layers, a first electrical connection existed between the first back drill verification feature (56, 74, 84, 102, 120) and the conductive material (54, 72, 82, 100, 114) before a first back drill operation, and the first back drill operation severed the first electrical connection.

2. The circuit board (14) according to claim 1 and further comprising:
a second signal trace (68, 96) present on a second inner layer of the circuit board (14), the via hole (70, 98) intersecting the second signal trace (68, 96), and the second signal trace (68, 96) in electrical contact with the conductive material (72, 100); and
a second back drill verification feature (76, 104) on a second layer of the circuit board (14), wherein the second inner layer and the second layer are different layers, a second electrical connection existed between the second back drill verification feature (76, 104) and the conductive material (72, 100) before a second back drill operation, and the second back drill operation severed the second electrical connection.

3. The circuit board (14) according to claim 1 wherein the first back drill verification feature (56, 74, 84) comprises a back drill verification signal trace having a length based on a wavelength of a test signal (128) carried by the first signal trace (50, 66, 78).

4. The circuit board (14) according to claim 3 wherein the length is equal to or greater than one-eighth the wavelength of the test signal (128).

5. The circuit board of (14) according to claim 1 wherein the first back drill verification feature (120) comprises a back drill verification signal trace in electrical contact with a second signal trace (124).

6. An electronic device (10) comprising:
a circuit board (14):
a signal trace (50, 66, 78, 94, 116) present on an inner layer of the circuit board (14);
a via hole (52, 70, 80, 98, 112) drilled through the circuit board (14) and intersecting the signal trace (50, 66, 78, 94, 116);
conductive material (54, 72, 82, 100, 114) in the via hole (52, 70, 80, 98, 112) and in electrical contact with the signal trace (50, 66, 78, 94, 116);
a back drill verification feature (56, 74, 84, 102, 120) on a layer of the circuit board (14), wherein the inner layer and the layer are different layers, an electrical connection existed between the back drill verification feature (56, 74, 84, 102, 120) and the conductive material (54, 72, 82, 100, 114) before a back drill operation, and the back drill operation severed the electrical connection; and
a plurality of components (16, 18, 20, 22, 88) and connectors (24, 26, 60) mounted on a first outer layer (46) of the circuit board (14), with at least one of the plurality of components (16, 18, 20, 22, 88) and connectors (24, 26, 60) in electrical contact with the conductive material (54, 72, 82, 100, 114).

7. The electronic device (10) according to claim 6 wherein the back drill verification feature (56, 74, 102) includes a test pad (56, 74, 110) present on one of the first outer layer (46) or a second outer layer (48).

8. The electrical device (10) according to claim 7 wherein the back drill verification feature (102) includes a via hole (106) having conductive material (108) provided therein, with the conductive material (108) in electrical contact with the test pad (110).

9. The electronic device (10) according to claim 6 wherein the back drill verification feature (56, 74, 84) comprises a back drill verification signal trace having a length based on a wavelength of a test signal (128) carried by the signal trace (50, 66, 78).

10. The electronic device (10) according to claim 6 wherein the back drill verification feature (120) comprises a back drill verification signal trace in electrical contact with a second signal trace (124).

11. A method of performing a back drill operation comprising:
drilling into a via hole (52, 70, 80, 98, 112) of a circuit board (14), thereby severing an electrical connection between conductive material (54, 72, 82, 100, 114) in the via hole (52, 70, 80, 98, 112) and a back drill verification feature (56, 74, 84, 102, 120).

12. The method according to claim 11 wherein a signal trace (50, 66, 78, 94, 116) is present on an inner layer of the circuit board (14) and is in electrical contact with the conductive material (54, 72, 82, 100, 114).

13. The method according to claim 12 wherein the back drill verification feature (56, 74, 84, 102) comprises a back drill verification signal trace having a length based on a wavelength of a test signal (128) carried by the signal trace (50, 66, 78, 94).

14. The method according to claim 11 wherein the back drill verification feature (56, 74, 102) includes a test pad (56, 74, 110) present on an outer layer (46, 48) of the circuit board (14).

15. The method according to claim 11 wherein the back drill verification feature (120) includes a back drill verification signal trace in electrical contact with a signal trace (124) both before and after drilling into the via hole (112).
